(19) United States
(12) Patent Application Publication
(10) Pub. No.: US 2012/0261721 A1
(43) Pub. Date: Oct. 18, 2012

(54) SEMICONDUCTOR STRUCTURES HAVING NUCLEATION LAYER TO PREVENT INTERFACIAL CHARGE FOR COLUMN III-V MATERIALS ON COLUMN IV OR COLUMN IV-IV MATERIALS

(75) Inventor: William E. Hoke, Wayland, MA (US)

(73) Assignee: Raytheon Company, Waltham, MA (US)

(21) Appl. No.: 13/088,813

(22) Filed: Apr. 18, 2011

(51) Int. Cl. H01L 29/267; H01L 21/20

(52) U.S. Cl. 257/200; 438/478; 257/E29.081; 257/E21.09

(57) ABSTRACT

A semiconductor structure having: a column IV material or column IV-IV material; a nucleation layer of AlN layer or a column III nitride having more than 60% aluminum content on a surface of the column IV material or column IV-IV material and a layer of column III-V material over the nucleation layer, where the nucleation layer and the layer of column III-V material over the nucleation layer have different crystallographic structures. In one embodiment, the column III-V nucleation layer is a nitride and the column III-V material of the over the nucleation layer is a non-nitride such as, for example, an arsenide (e.g., GaAs), a phosphide (e.g., InP), or an antimonide (e.g. InSb), or alloys thereof.

### TECHNICAL FIELD

This disclosure relates generally to semiconductor structures and more particularly to semiconductor structures having nucleation layers to prevent interfacial charge for column III-V materials on column IV materials.

### BACKGROUND

As is known in the art, new technologies are emerging from the on-wafer integration of III-V circuitry with silicon circuitry. Furthermore significant cost savings are possible with the deposition of III-V material on large area, inexpensive silicon and germanium (column IV) substrates. Both these efforts require depositing III-V materials on layers of silicon or germanium or on substrates of silicon or germanium creating a column III-V/IV interface. A serious challenge for growth of III-V materials on column IV materials is interdiffusion at the III-V/IV interface which causes significant conducting interface charge since III-V elements dope column IV materials and visa versa. For example, for GaAs grown on silicon, gallium and arsenic dope silicon and silicon dopes GaAs. Since one atomic plane contains 1×10¹⁵atoms/cm² and the electronic sheet density of some HEMTs is approximately 1×10¹³ carriers/cm², the interdiffusion of just two atomic planes at the heterojunction between III-V and column IV materials will result in significant interfacial charge The amount of interdiffusion can be further increased by the thermal budget of the growth process or subsequent circuit fabrication process.

Thus, there is significant interfacial charge encountered when growing III-V materials on column IV silicon or germanium surfaces and column IV-IV SiC or SiGe surfaces. The interfacial charge causes poor device pinch-off and significant microwave loss, degrading device performance.

As is also known in the art, aluminum nitride (AlN) has been used as a nucleation layer for growth of gallium nitride (GaN) and GaN HEMTs on silicon where the AlN and the GaN have the same crystallographic structures (i.e., nitrides have a Wurtzite or hexagonal crystal structure whereas arsenides, phosphides, and antimonides have a Zinc Blende crystal structure).

As reported in a paper by Hoke et al., J. Vac. Sci. Technol. B 29(3), May/June 2011, AlN can be grown on silicon without interfacial charge. Also known in the art is that interfacial charge is a significant issue for growth of arsenides, phosphides, and antimonides on column IV materials since arsenic, phosphorus, and antimony dope column IV materials and column IV materials dope arsenides, phosphides, and antimonides. When nitrogen diffuses into silicon or germanium conducting holes or electrons are not created, reference being made to the well-known textbook by Sze (Physics of Semiconductor Devices, page 21, 1981) wherein no electronic energy levels are listed for nitrogen in silicon or germanium. AlN (or a column III nitride having more than 60% aluminum content) is extremely hard to dope. Consequently silicon or germanium diffusing into AlN does not cause significant conduction. AlN (or a column III nitride having more than 60% aluminum content) is different than the non-nitride III-V materials in not causing interface charge because phosphorus, arsenic, and antimony readily dope silicon and germanium, using column III phosphides, arsenides, and antimonides therefore will cause interface charge. Furthermore silicon or germanium dope arsenides, phosphides, and antimonides. Among the other column III-nitrides, GaN and InN are readily doped with silicon and germanium.

### SUMMARY

In accordance with the present disclosure, a semiconductor structure is provided, comprising: a column IV material or a column IV-IV material; a nucleation layer of a column III-V material on a surface of the column IV material or column IV-IV material; and a layer of column III-V material on the nucleation layer, where the nucleation layer and the layer of column III-V material have different crystallographic structures.

In one embodiment, the column IV material or column IV-IV material is Si, Ge, SiGe, or SiC

In one embodiment, the nucleation layer includes AlN.

In one embodiment, the nucleation layer is a column III nitride having more than 60% aluminum content.

In one embodiment the nucleation layer is AlₓGa₁₋ₓN having an Alₓ value greater than or equal to 0.6 (that is, 60% aluminum concentration)

In one embodiment, the nucleation layer is AlN.

In one embodiment, the column V element in the column III-V material over the nucleation layer is an element other then nitrogen.

In one embodiment, the column V element in the column III-V material over the nucleation layer is an element other then nitrogen and the column III-V layer is disposed in contact with the nucleation layer.

In one embodiment, a semiconductor structure is provided, comprising: a column IV material or column IV-IV material; a first layer of a column III-V material on a surface of the a column IV material or column IV-IV material, wherein the column V element of the first layer is nitrogen; and a second layer of column III-V material disposed over the first layer, where the column V element of the second layer is an element other then nitrogen.

In one embodiment, the first layer is AlN or a column III nitride having more than 60% aluminum content and the second layer includes an arsenide, phosphide, antimonide, or alloys thereof such as AlGaAs, AlGaInAs, GaAsP, and GaInAsP.

In one embodiment, the first layer is AlN or a column III nitride having more than 60% aluminum content and the layer of column III-V material disposed over the nucleation layer includes GaAs, InP, InSb, or alloys thereof such as GaAsP.

In one embodiment, a semiconductor structure is provided, comprising: a column IV material or column IV-IV material; a first layer of a column III-V material on a surface of the column IV or column IV-IV material; and a second layer of column III-V material disposed over the first layer; and/wherein the first layer and the second layer have different crystal structures.

With such structures, an AlN layer or a column III nitride having more than 60% aluminum content is used as a nucleation layer for growth of III-V materials on column IV or column IV-IV material (e.g., silicon, germanium, SiGe, and SiC substrates) without interface charge caused by the column IV material doping the III-V material or visa versa. The AlN layer or a column III nitride having more than 60% aluminum content is used as a nucleation layer on column IV or column IV-IV material for subsequent growth of III-V materials which are not nitrides (e.g., materials that include: arsenides such as GaAs, phosphides such as InP, antimonides such as InSb and their alloys thereof such as GaAsP). AlN or a column III nitride having more than 60% aluminum content is not an obvious nucleation layer because these materials has a hexagonal crystal structure (i.e., a Wurtzite crystal structure) whereas the arsenides, phosphides, and antimonides have the Zinc blende crystal structure. While crystalline defects may be formed at the AlN/GaAs (etc.) interface; however, being both III-V materials, AlN and GaAs will not cross dope each other so interface charge will not occur. Thus, while exchanging one problem (interface charge) for another problem (crystalline defects from different crystal structures), it is noted that with some materials crystalline defect problems can be mitigated through improved growth processes or a particularly tolerant material structure or device application; however, the interface charge problem is a significant issue for many device structures by causing parasitic conduction, reduced device efficiency, poor pinch-off characteristics and high microwave loss.

The details of one or more embodiments of the disclosure are set forth in the accompanying drawings and the description below. Other features, objects, and advantages of the disclosure will be apparent from the description and drawings, and from the claims.

### DESCRIPTION OF DRAWINGS

FIG. 1 is a semiconductor structure according to the disclosure; and

FIG. 2 is a semiconductor structure according another embodiment of the disclosure.

Like reference symbols in the various drawings indicate like elements.

### DETAILED DESCRIPTION

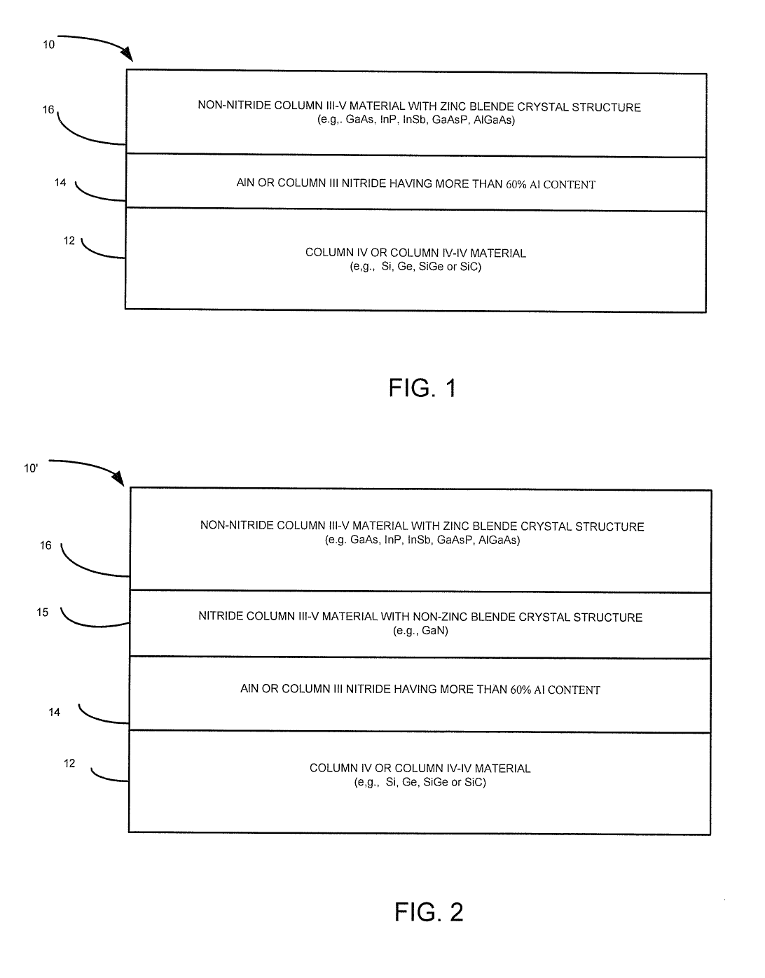

Referring now to FIG. 1, a semiconductor structure 10 is shown having a column IV or column IV-IV material, here, for example, a layer or substrate 12 of single crystal silicon, germanium, or SiC; a nucleation layer 14 of AlN or a column III nitride having more than 60% aluminum content having a wurtzite crystal structure on a surface of the column IV or column IV-IV material; and a layer 16 of a non-nitride column III-V material (e.g., materials that include: arsenides such as GaAs, phosphides such as InP, antimonides such as InSb and column III-V alloys, such AlGaAs and GaAsP) over the nucleation layer 14, where the nucleation layer 14 and the layer 16 of column III-V material are different materials and have different crystal structures. Here, for example, the substrate has a (111) crystallographic orientation. Here, nucleation layer 14 has a wurtzite crystal structure, the column III-V material over the nucleation layer 14 being non-nitrides such as, for example, arsenides (e.g., GaAs), phosphides (e.g., InP), and antimonides (e.g., InSb) having the zinc blende crystal structure.

In forming a nucleation layer 14 of AlN or a column III nitride having more than 60% aluminum content using, for example, electron beam deposition or molecular beam epitaxy grown on the column IV or IV-IV layer 12, the process begins by initiating the growth with a flux of nitrogen atoms before the flux of group III atoms. This is because group III atoms conductivity dope silicon, germanium, and SiC so the nitrogen flux is initiated first.

This method of using an AlN or a column III nitride having more than 60% aluminum content layer 14 on a silicon or germanium surface layer 12 for preventing interfacial charge from typical diffusion processes in which the diffusing silicon, germanium, or carbon (from SiC) atoms are contained within the AlN layer 14 (or a column III nitride having more than 60% aluminum content) applies to all non-nitride column III-V materials including column III-V binaries (such as GaAs, InP, InSb, GaN), column III-V ternaries (such as InGaAs, AlGaAs, InAsSb, AlGaN, etc.), III-V quarternaries, and higher column III-V substituent mixtures. These column III-V materials are grown on top of the AlN nucleation layer or a column III nitride having more than 60% aluminum content layer 14 on silicon, germanium, SiGe, or SiC layer 12 to provide an insulating interface.

It is noted that the disclosure also applies to growing other column III-Nitride materials on top of layer 14 and then growing non-nitride III-V materials 16 which have a different crystal structure than the column III-Nitride material. For example, consider growth of GaAs on silicon. Growing GaN (or some other nitride material or alloy) on top of the AlN or a column III nitride having more than 60% aluminum content layer 14 may be performed before growing the GaAs. For example, referring to FIG. 2, the structure 10′ shows a GaAs 16 layer may be grown on GaN layer 15 (an example of structure 10′, FIG. 2 is: GaAs/GaN/AlN/Si Substrate) instead of directly on AlN or a column III nitride having more than 60% aluminum content layer 14 (an example of structure 10, FIG. 1, is: GaAs/AlN/Si Substrate). Consequently the disclosure apples to growing other nitride materials on top of the AlN or a column III nitride having more than 60% aluminum content nucleation layer 14 prior to growing the non-nitride III-V materials, as shown in FIG. 2. Growing another nitride material on top of AlN before growing the non-nitride III-V material may be beneficial in mitigating defects caused by the different crystal structures.

A number of embodiments of the disclosure have been described. Nevertheless, it will be understood that various modifications may be made without departing from the spirit and scope of the disclosure. Accordingly, other embodiments are within the scope of the following claims.

What is claimed is:

1. A semiconductor structure, comprising:
a column IV material or column IV-IV material;
a nucleation layer of a column of III-V material on a surface of the column IV material or column IV-IV material;
a layer of column III-V material on the nucleation layer; and
wherein the nucleation layer and the layer of column III-V material are different crystallographic structures.

2. The semiconductor structure recited in claim 1 where the column IV material or column IV-IV material is Si, Ge, SiGe, or SiC.

3. The semiconductor structure recited in claim 1 wherein the nucleation layer is AlN or a column III nitride having more than 60% aluminum content.

4. The semiconductor structure recited in claim 3 where the column IV material or column IV-IV material is Si, Ge, SiGe, or SiC.

5. The semiconductor structure recited in claim 4 wherein the nucleation layer is AlN or a column III nitride having more than 60% aluminum content

6. The semiconductor structure recited in claim 3 wherein the column V element in the column III-V material over the nucleation layer is an element other than nitrogen.

7. The semiconductor structure recited in claim 5 wherein the column V element in the column III-V material over the nucleation layer is an element other than nitrogen.

8. The semiconductor structure recited in claim 3 wherein the column V element in the column III-V material over the nucleation layer is an element other than nitrogen and wherein such layer of column III-V material is disposed in contact with the nucleation layer.

9. The semiconductor structure recited in claim 5 wherein the column V element in the column III-V material over the nucleation layer is an element other than nitrogen and wherein such layer of column III-V material is disposed in contact with the nucleation layer.

10. A semiconductor structure, comprising:
a column IV material or a column IV-IV material;
a first layer of a column III-V material on a surface of the column IV material or column IV-IV material, wherein the column V element of the first layer is nitrogen; and
a second layer of column III-V material disposed over the first layer, where the column V element of the second layer is an element other than nitrogen.

11. The semiconductor structure recited in claim 10 wherein the first layer is AlN or a column III nitride having more than 60% aluminum content and the second layer is a material including: an arsenide, a phosphide, an antimonide, or alloys thereof.

12. The semiconductor structure recited in claim 10 wherein the first layer is AlN or a column III nitride having more than 60% aluminum content and the second layer is a material including: GaAs, InP or InSb, or alloys thereof.

13. A semiconductor structure, comprising:
a column IV material or column IV-IV material;
a first layer of a column III-V material on a surface of the a column IV material or column IV-IV material; and
a second layer of column III-V material disposed over the first layer; and
wherein the first layer and the second layer have different crystal structures.

14. The semiconductor structure recited in claim 13, where the first layer has the column V element nitrogen and the second layer has a column V element other than nitrogen.

15. The semiconductor structure recited in claim 13 where the first layer has a wurtzite crystal structure and the second layer has a zinc blende crystal structure.

16. The semiconductor structure recited in claim 15 where the second layer is in contact with the first layer.

17. The semiconductor structure recited in claim 15 where the first layer is a nitride and the second layer is a material including: an arsenide, a phosphide, an antimonide, or alloys thereof.

18. The semiconductor recited in claim 17 wherein the first layer is AlN or a column III nitride having more than 60% aluminum content and the second layer is a material including: GaAs, InP or InSb, or alloys thereof.

19. The semiconductor structure recited in claim 16 where the first layer is a nitride and the second layer is a material including: an arsenide, a phosphide, an antimonide, or alloys thereof.

20. The semiconductor recited in claim 19 wherein the first layer is AlN or a column III nitride having more than 60% aluminum content and the second layer is a material including: GaAs, InP or InSb, or alloys thereof.

21. The semiconductor structure recited in claim 1 wherein the nucleation layer has a wurtzite crystal structure and the layer of column III-V material has a zinc blende crystal structure.

22. The semiconductor structure recited in claim 10 wherein the first layer has a wurtzite crystal structure and the second layer has a zinc blende crystal structure.

23. The semiconductor structure recited in claim 13 wherein the first layer has a wurtzite crystal structure and the second layer has a zinc blende crystal structure.

24. The semiconductor recited in claim 21 including a layer of nitride material between the first layer and the second layer.

25. The semiconductor recited in claim 1 including a layer of nitride material between the nucleation layer and the layer of column III-V material.

26. A method for forming a semiconductor structure, comprising:
a column IV material or column IV-IV material;
forming a first layer of a column III-V material on a surface of a column IV material or column IV-IV material, wherein the first layer is aluminum nitride or a column III nitride having more than 60% aluminum content and wherein the nitrogen portion is formed on the column IV material or column IV-IV material prior to forming the aluminum portion; and
forming a second layer of column III-V material over the first layer, where the column V element of the second layer is an element other than nitrogen.
